(19) United States
(12) Patent Application Publication
(10) Pub. No.: US 2026/0011582 A1
(43) Pub. Date: Jan. 8, 2026

(54) FILTER ASSEMBLY AND PICK-AND-PLACE APPARATUS INLCUDING THE SAME

(71) Applicant: Samsung Electronics Co., Ltd., Suwon-si (KR)

(72) Inventors: Yeongseok KIM, Suwon-si (KR); Ilhyoung KOO, Suwon-si (KR); Kisu EUM, Suwon-si (KR)

(73) Assignee: Samsung Electronics Co., Ltd., Suwon-si (KR)

(21) Appl. No.: 19/080,314

(22) Filed: Mar. 14, 2025

(30) Foreign Application Priority Data
Jul. 8, 2024 (KR) 10-2024-0089669

(51) Int. Cl. H01L 21/67; H01L 21/683

(52) U.S. Cl. CPC H01L 21/67144; H01L 21/67017; H01L 21/6838

(57) ABSTRACT

A pick-and-place apparatus includes a filter assembly configured to supply vacuum pressure and air pressure from a vacuum ejector to at least one picker nozzle. The filter assembly includes a first pneumatic line connecting a first port connected to the vacuum ejector and a second port connected to the at least one picker nozzle, a filter in the first pneumatic line and filtering gas flowing from the second port to the first port, a second pneumatic line branched from the first pneumatic line in a front-end portion and in a rear-end portion of the filter to allow gas to bypass the filter, a first shut-off valve in the first pneumatic line to block flow of gas from the first port to the second port, and a second shut-off valve in the second pneumatic line to block flow of gas from the second port to the first port.

### PRIORITY STATEMENT

This application claims priority under 35 U.S.C. § 119 to Korean Patent Application No. 10-2024-0089669, filed on Jul. 8, 2024 in the Korean Intellectual Property Office (KIPO), the contents of which are herein incorporated by reference in their entirety.

### BACKGROUND

### 1. Field

Example embodiments relate to a filter assembly and a pick-and-place apparatus including the same. More particularly, example embodiments relate to a filter assembly for filtering a gas sucked from a pick-up nozzle for absorbing and transporting a semiconductor device, and a pick-and-place apparatus including the same.

### 2. Description of the Related Art

In manufacturing a semiconductor package, the semiconductor package that has been manufactured may undergo a test process for inspecting a defective state, a marking process for imprinting a product number, etc., on a surface of the package, an appearance inspection process using a vision camera, and a tape and reel process for packing by sealing with a cover tape. In each of these processes, a product such as the semiconductor package may be transported using a pick-and-place apparatus. The pick-and-place apparatus may include a pipe (e.g., an air pressure line for supplying air pressure) for providing vacuum pressure and air pressure to each of a plurality of pickers for adsorbing or de-adsorbing the product, and an air filter installed in the pipe. In related arts, since intake and exhaust are performed through a single pipe, when the air pressure is provided to an adsorption pad of the picker through the single pipe, dust inside the air filter is discharged together, thereby contaminating the inside of the process equipment and the surface of the product.

### SUMMARY

Example embodiments provide a pick-and-place apparatus including a filter assembly configured to prevent (or reduce) contamination of an inside of a facility and a surface of a product due to dust inside a pneumatic filter.

Example embodiments provide a filter assembly for the pick-and-place apparatus.

Some example embodiments of inventive concepts provide a pick-and-place apparatus including a picker module having at least one picker nozzle configured to adsorb or release a semiconductor device by vacuum pressure and air pressure, a vacuum ejector configured to selectively supply any one of the vacuum pressure and the air pressure to the at least one picker nozzle, and a filter assembly configured to supply the vacuum pressure and the air pressure from the vacuum ejector to the at least one picker nozzle. The filter assembly includes a first pneumatic line connecting a first port connected to the vacuum ejector and a second port connected to the at least one picker nozzle, a filter in the first pneumatic line and configured to filter gas flowing from the second port to the first port, a second pneumatic line branched from the first pneumatic line in a front-end portion and in a rear-end portion of the filter to allow gas to bypass the filter, a first shut-off valve in the first pneumatic line and configured to block flow of gas from the first port to the second port, and a second shut-off valve in the second pneumatic line and configured to block flow of gas from the second port to the first port.

Some example embodiments of inventive concepts provide a pick-and-place apparatus including a picker module having a plurality of picker nozzles, each picker nozzle of the plurality of picker nozzles being configured to adsorb or release a semiconductor device by vacuum pressure and air pressure, a vacuum ejector having a plurality of manifold blocks for selectively supplying any one of the vacuum pressure and the air pressure to a respective picker nozzle of the plurality of picker nozzles, and a filter assembly configured to supply the vacuum pressure and the air pressure from the plurality of manifold blocks to each picker nozzle of the plurality of picker nozzles. The filter assembly includes an intake line connecting a first port connected to a manifold block of the plurality of manifold blocks and a second port connected to a picker nozzle of the plurality of picker nozzles, a filter in the intake line and configured to filter gas flowing from the second port to the first port, a bypass line branched from the intake line in a front-end portion and a rear-end portion of the filter to allow gas to bypass the filter, a first check valve in the intake line to block flow of gas from the first port to the second port, and a second check valve in the bypass line to block flow of gas from the second port to the first port.

Some example embodiments of inventive concepts provide a filter assembly for a pick-and-place apparatus including a first port to which vacuum pressure and air pressure are selectively supplied, a second port configured to receive the vacuum pressure and the air pressure, and exhaust the vacuum pressure and the air pressure to outside the pick-and-place apparatus, an intake line connecting the first port and the second port, a filter in the intake line and configured to filter gas flowing from the second port to the first port, a bypass line branched from the intake line in a front-end portion and a rear-end portion of the filter, and configured to allow gas to bypass the filter, a first check valve in the intake line to block flow of gas from the first port to the second port, and a second check valve in the bypass line to block flow of gas from the second port to the first port.

Some example embodiments of inventive concepts provide a filter assembly of a pick-and-place apparatus that may be configured to supply vacuum pressure and air pressure from a vacuum ejector to a picker nozzle. The filter assembly may include a first pneumatic line connecting a first port and a second port, a filter in the first pneumatic line, a second pneumatic line branched from the first pneumatic line to allow gas to bypass the filter, a first shut-off valve in the first pneumatic line and configured to block the flow of gas from the first port to the second port, and a second shut-off valve in the second pneumatic line and configured to block the flow of gas from the second port to the first port.

The filter in the first pneumatic line may be configured to filter the gas sucked from the picker nozzle during a gripping operation of the picker nozzle to collect foreign substances such as dust. During a gripping release operation of the picker nozzle, the first pneumatic line may be blocked and air pressure may be supplied to the picker nozzle through the second pneumatic line. Accordingly, it may be possible to prevent (or reduce) dust collected in the filter in the first pneumatic line from leaking into the process equipment through the picker nozzle and contaminating the inside of a process equipment and a surface of a product such as a semiconductor package.

### BRIEF DESCRIPTION OF THE DRAWINGS

Example embodiments will be more clearly understood from the following detailed description taken in conjunction with the accompanying drawings. FIGS. 1 to 13 represent non-limiting, example embodiments as described herein.

FIG. 1 is a front view illustrating a pick-and-place apparatus in accordance with some example embodiments.

FIG. 2 is a side view illustrating the pick-and-place apparatus of FIG. 1.

FIG. 3 is a pneumatic circuit diagram illustrating the pick-and-place apparatus of FIG. 1.

FIG. 4 is a pneumatic circuit diagram illustrating a vacuum ejector of FIG. 3.

FIG. 5 is a cross-sectional view illustrating a filter assembly of the pick-and-place apparatus of FIG. 1.

FIG. 6A is a cross-sectional view illustrating a gripping operation of a picker nozzle when vacuum pressure is supplied to the filter assembly of FIG. 5.

FIG. 6B is a cross-sectional view illustrating a gripping release operation of the picker nozzle when air pressure is supplied to the filter assembly of FIG. 5.

FIG. 7 is a cross-sectional view illustrating a filter assembly for a pick-and-place apparatus in accordance with some example embodiments.

FIG. 8A is a timing diagram illustrating a pick-up step.

FIG. 8B is a timing diagram illustrating a place step.

FIG. 9 is a plan view illustrating a filter assembly in accordance with some example embodiments.

FIG. 10 is a side view illustrating the filter assembly of FIG. 9.

FIG. 11 is a plan view illustrating a filter assembly in accordance with some example embodiments.

FIG. 12 is a side view illustrating the filter assembly of FIG. 11.

FIG. 13 is a perspective view illustrating the filter assembly of FIG. 11.

### DETAILED DESCRIPTION

Hereinafter, some example embodiments will be explained in detail with reference to the accompanying drawings.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

When the terms “approximately,” “about” or “substantially” are used in this specification in connection with a numerical value, it is intended that the associated numerical value includes a manufacturing or operational tolerance (e.g., ±10%) around the stated numerical value. Moreover, when the words “approximately,” “about” and “substantially” are used in connection with geometric shapes, it is intended that precision of the geometric shape is not required but that latitude for the shape is within the scope of the disclosure. Further, regardless of whether numerical values or shapes are modified as “approximately,” “about” or “substantially,” it will be understood that these values and shapes should be construed as including a manufacturing or operational tolerance (e.g., ±10%) around the stated numerical values or shapes.

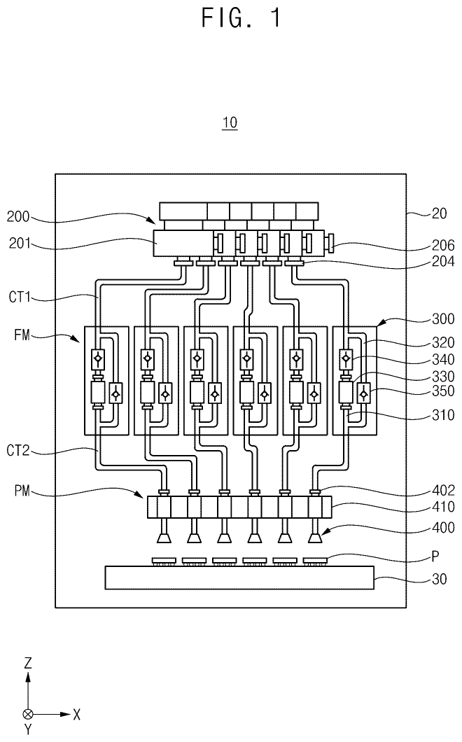

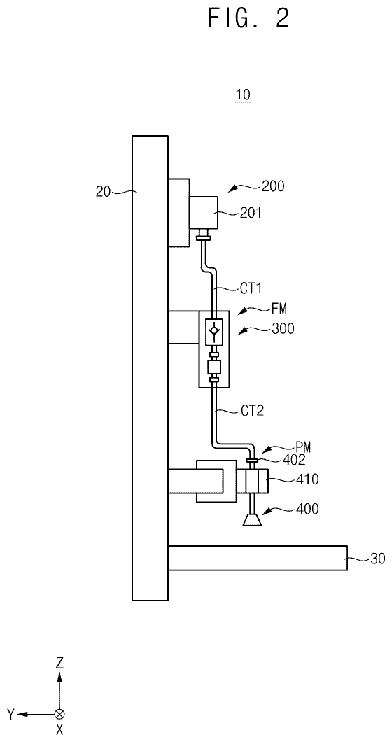

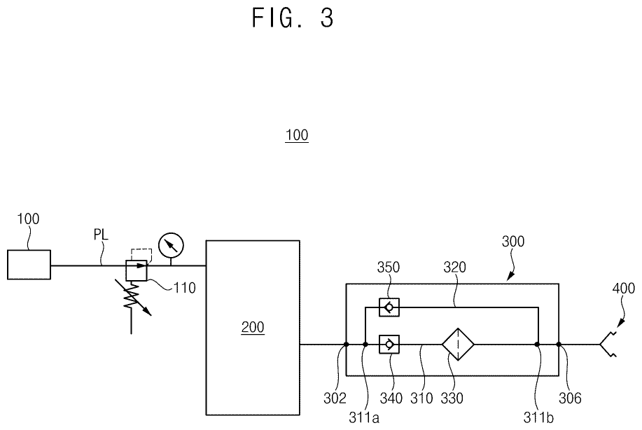

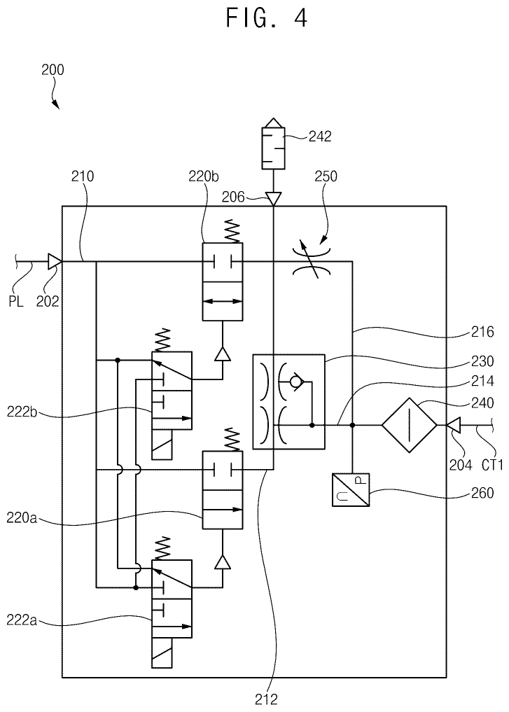

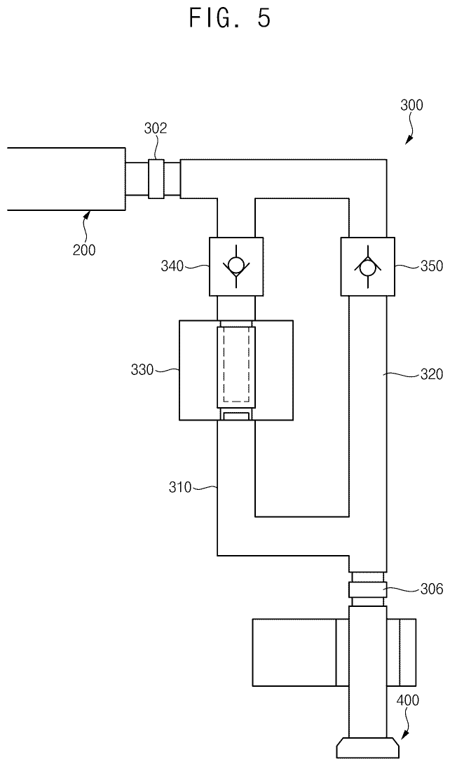

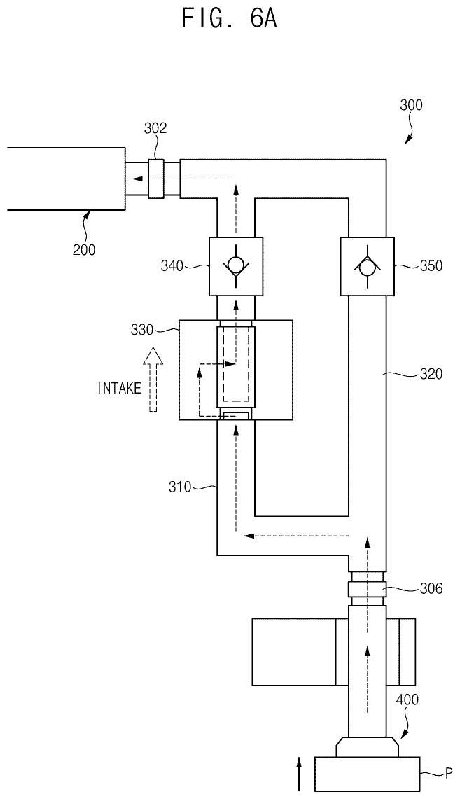

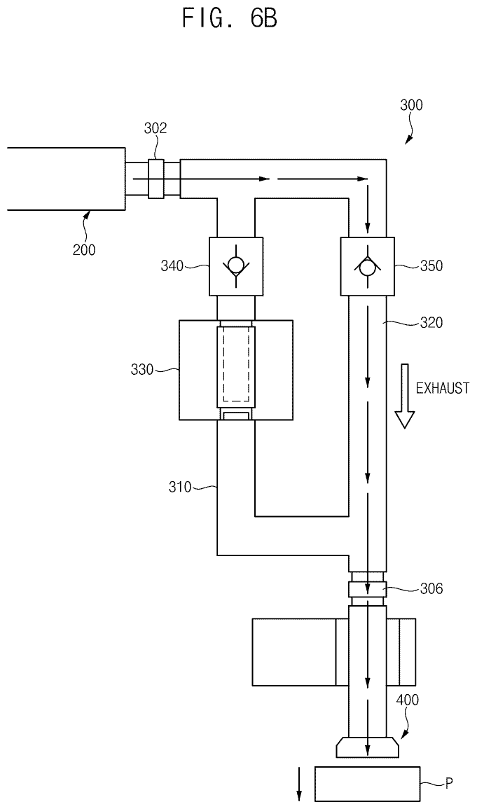

FIG. 1 is a front view illustrating a pick-and-place apparatus in accordance with some example embodiments. FIG. 2 is a side view illustrating the pick-and-place apparatus of FIG. 1. FIG. 3 is a pneumatic circuit diagram illustrating the pick-and-place apparatus of FIG. 1. FIG. 4 is a pneumatic circuit diagram illustrating a vacuum ejector of FIG. 3. FIG. 5 is a cross-sectional view illustrating a filter assembly of the pick-and-place apparatus of FIG. 1. FIG. 6A is a cross-sectional view illustrating a gripping operation of a picker nozzle when vacuum pressure is supplied to the filter assembly of FIG. 5, and FIG. 6B is a cross-sectional view illustrating a gripping release operation of the picker nozzle when air pressure is supplied to the filter assembly of FIG. 5.

Referring to FIGS. 1 to 6B, the pick-and-place apparatus 10 may include a vacuum ejector 200, a filter assembly 300, and a picker module PM. In addition, the pick-and-place apparatus 10 may further include a vertical support frame 20 and a stage 30. In the present disclosure, a single filter assembly 300 may be referred to as “the filter assembly 300,” and two or more filter assemblies (or two or more of “the filter assembly 300”) may be referred to as “the plurality of filter assemblies 300.”

In some example embodiments, the pick-and-place apparatus 10 may be provided for a transport device for transporting a product such as a semiconductor package P. For example, the pick-and-place apparatus 10 may be a device for sucking and transporting the semiconductor package P in manufacturing equipment configured to perform one or more of a test process, an inspection process, a tape and reel process, etc., to manufacture a semiconductor package. In the present disclosure, a single semiconductor package P may be referred to as “the semiconductor package P,” and two or more semiconductor packages (or two or more of “the semiconductor package P”) may be referred to as “semiconductor packages P” or “the semiconductor packages P.”

As illustrated in FIGS. 1 and 2, the vertical support frame 20 may extend in a vertical direction (Z direction) within the manufacturing equipment. The vacuum ejector 200, the filter assembly 300, and the picker module PM may be installed on one side of the vertical support frame 20, but example embodiments are not limited thereto. For example, the vacuum ejector 200, the filter assembly 300, and the picker module PM may be sequentially arranged in the vertical direction (Z direction), but example embodiments are not limited thereto.

Semiconductor packages P may be disposed on the stage 30. For example, a customer tray including semiconductor packages P thereon may be loaded on the stage 30. The picker module PM may include a plurality of picker nozzles 400, and the vacuum ejector 200 may supply vacuum pressure (e.g., negative pressure) to the plurality of picker nozzles 400 to suction and transport the semiconductor packages P to a predetermined position (or a desired position) on the stage 30, and the vacuum ejector 200 may supply air pressure (e.g., positive pressure) to the plurality of picker nozzles 400 at the predetermined position (or a desired position) to detach the semiconductor packages P from the plurality of picker nozzles 400. In some example embodiments, the vacuum pressure may be referred to as a pressure lower than atmospheric pressure, and the air pressure may be referred to as a pressure higher than atmospheric pressure.

In some example embodiments, the picker module PM may include a mounting body 410 extending in a first direction (X direction) and the plurality of picker nozzles 400 sequentially mounted on the mounting body 410 in the first direction (X direction). The mounting body 410 of the picker module PM may be mounted on a transport robot (not illustrated in FIG. 1). Accordingly, the picker module PM may be moved in a horizontal direction (XY direction) and a vertical direction (Z direction) by the transport robot. For example, the plurality of picker nozzles 400 may be arranged in a matrix form of one or two rows.

An input/output port 402 may be connected to a first surface of the mounting body 410, and a picker nozzle of the plurality of picker nozzles 400 may be connected to the input/output port 402 though the mounting body 410. The vacuum pressure and the air pressure may be output (e.g., supplied) to the picker nozzle of the plurality of picker nozzles 400 through the input/output port 402. In the present disclosure, a single picker nozzle of the plurality of picker nozzles 400 may be referred to as “the picker nozzle 400,” and “at least one picker nozzle 400” may refer to one or more of “the picker nozzle 400.”

In some example embodiments, the vacuum ejector 200 may be configured to selectively supply any one of the vacuum pressure and the air pressure to at least one picker nozzle 400. The vacuum ejector 200 may include a plurality of manifold blocks 201 for selectively supplying the vacuum pressure and the air pressure to each picker nozzle of the plurality of picker nozzles 400 of the picker module PM.

As illustrated in FIG. 3, the vacuum ejector 200 may be configured to generate vacuum pressure or air pressure by using compressed air supplied from a compressed air supply source 100 through a process line PL, and may be further configured to supply the generated vacuum pressure or air pressure to the plurality of picker nozzles 400 through the filter assembly 300.

An air pressure regulator 110 may be installed in the process line PL. The air pressure regulator 110 may be configured to regulate the air pressure supplied from the compressed air supply source 100 to the plurality of manifold blocks 201 of the vacuum ejector 200. For example, the air pressure regulator 110 may include a relief valve as a regulator. The relief valve may limit the pressure of the air pressure flowing through the process line PL to a desired pressure. For example, the pressure of the air pressure regulated by the air pressure regulator 110 may be within a range of approximately 5 bar to 6 bar, but example embodiments are not limited thereto.

As illustrated in FIG. 4, each manifold block of the plurality of manifold blocks 201 of the vacuum ejector 200 may include a supply port 202 to which the compressed air may be supplied from the compressed air supply source 100, internal passages (also referred to as passageway) 210, 214, 216, control valves 220a, 220b, a vacuum generator 230 configured to generate vacuum pressure or air pressure using the supplied compressed air, and a vacuum port 204 to which the generated vacuum pressure or air pressure may be supplied.

The compressed air introduced through the supply port 202 may be supplied to an intake control valve 220a and an air supply (e.g., exhaust) control valve 220b through an introduction air passage 210. For example, when the intake control valve 220a is opened by a pilot pressure of a first solenoid valve 222a, the compressed air may be supplied to a supply passage 212. The compressed air supplied above may flow through the vacuum generator 230 to generate vacuum pressure. The vacuum pressure of the vacuum generator 230 may be supplied to the vacuum port 204 through a vacuum intake passage 214. Accordingly, the vacuum pressure may be supplied to the filter assembly 300 by a first connecting tube CT1 connected to the vacuum port 204.

In some example embodiments, the compressed air supplied through the supply passage 212 may sequentially pass through a nozzle, a first diffuser, and a second diffuser of the vacuum generator 230, and then may be discharged to the outside through a discharge port 206. At this time, the vacuum pressure may be generated by sucking air from a first gap between the nozzle and the first diffuser, and a second gap between the first diffuser and the second diffuser. For example, when the vacuum pressure in the vacuum intake passage 214 is greater than the vacuum pressure in a connection opening connected to the second gap, a check valve may be closed so that only the vacuum pressure generated by the first gap flows, thereby generating a high vacuum pressure.

Additionally or alternatively, an intake filter 240 may be installed between the vacuum intake passage 214 and the vacuum port 204. The intake filter 240 may filter and remove foreign substances in the gas suctioned from the vacuum port 204 to prevent (or reduce) malfunction or deterioration of the vacuum ejector 200. A silencer 242 may be connected to the discharge port 206 provided on one side of the plurality of manifold blocks 201. The silencer 242 may be configured to suppress discharge noise of the compressed air discharged from the vacuum generator 230 and may release it to the outside air. A pressure sensor 260 may be connected to the vacuum intake passage 214 through a sensor passage and may be configured to measure a pressure of the vacuum pressure in the vacuum intake passage 214. Accordingly, the vacuum pressure supplied to the plurality of picker nozzles 400 by the vacuum ejector 200 may be measured by the pressure sensor 260.

Meanwhile, when the intake control valve 220a is closed and the exhaust control valve 220b is opened by a pilot pressure of a second solenoid valve 222b, the supply of compressed air may be stopped, so that the passage from the vacuum intake passage 214 to the vacuum generator 230 may be closed. Accordingly, the compressed air supplied from the exhaust control valve 220b may be supplied to the vacuum port 204 through a pressurizing passage 216 without being discharged to the outside through the vacuum generator 230. Accordingly, a large amount (or an amount) of high-pressure compressed air may be supplied to the filter assembly 300 through the first connecting tube CT1 connected to the vacuum port 204. Additionally or alternatively, a flow rate control valve 250 may be installed in the pressurizing passage 216. The flow rate control valve 250 may be configured to control the pressure and flow rate of the compressed air passing through the pressurizing passage 216. For example, the flow control valve may include an orifice, but example embodiments are not limited thereto. The air pressure supplied through the vacuum port 204 may be in a range of approximately 70 kPa to 100 kPa, but example embodiments are not limited thereto.

In some example embodiments, the filter assembly 300 may include a passage block extending in one direction and the plurality of filter assemblies 300. The plurality of filter assemblies 300 may be sequentially arranged in the passage block to be provided as a filter module FM that may function as a plurality of filtering devices. Each filter assembly of the plurality of filter assemblies 300, which collectively may function as a plurality of pneumatic filtering devices, may be configured to supply the vacuum pressure and the air pressure from a respective manifold block of the plurality of manifold blocks 201 to a respective picker nozzle of the plurality of picker nozzles 400.

As illustrated in FIGS. 4 and 5, the filter assembly 300, as a single pneumatic filtering device, may include a first pneumatic line 310 connecting a first port 302 connected to the vacuum ejector 200 and a second port 306 connected to a picker nozzle 400 of the plurality of picker nozzles 400, a filter 330 installed in the first pneumatic line 310 and configured to filter gas flowing from the second port 306 to the first port 302, and a second pneumatic line 320 branched from the first pneumatic line 310 and configured to allow the gas to bypass the filter 330. The first port 302 may be connected to the vacuum port 204 of the vacuum ejector 200 by the first connecting tube CT1. The second port 306 may be connected to the input/output port 402 of the picker nozzle 400 by a second connecting tube CT2.

Additionally or alternatively, the filter assembly 300 may include a first shut-off valve 340 installed in the first pneumatic line 310 configured to block the flow of gas from the first port 302 to the second port 306, and a second shut-off valve 350 installed in the second pneumatic line 320 configured to block the flow of gas from the second port 306 to the first port 302.

The first pneumatic line 310 may serve as an intake line for supplying vacuum pressure generated in the vacuum ejector 200 to the picker nozzle 400. The second pneumatic line 320 may be branched from a first branch 311a of the first pneumatic line 310 in front of (or adjacent to) the filter 330 and connected to a second branch 311b of the first pneumatic line 310 in rear of (or adjacent to) the filter 330. The second pneumatic line 320 may serve as a bypass line for allowing the gas to bypass the filter 330. The second pneumatic line 320 may serve as an exhaust line for supplying air pressure generated in the vacuum ejector 200 to the picker nozzle 400.

The first shut-off valve 340 may be installed in the first pneumatic line 310 and may be configured to block the flow of gas from the vacuum ejector 200 to the picker nozzle 400 through the first pneumatic line 310. The first shut-off valve 340 may be installed in the first pneumatic line 310 between the first port 302 and the filter 330. The first shut-off valve 340 may be installed in a front-end portion of the filter 330. The second shut-off valve 350 may be installed in the second pneumatic line 320 and may be configured to block the flow of gas from the picker nozzle 400 to the vacuum ejector 200 through the second pneumatic line 320.

For example, the first shut-off valve 340 may include a one-way check valve configured to open and close based on a differential pressure between the first port 302 and the second port 306, and allow the flow of gas (or only the flow of gas) from the second port 306 to the first port 302. The second shut-off valve 350 may include a one-way check valve configured to open and close based on a differential pressure between the second port 306 and the first port 302, and allow the flow of gas (or only the flow of gas) from the first port 302 to the second port 306.

Alternatively or additionally, the first and second shut-off valves 340, 350 may include an on/off valve that may be configured to open and close the first pneumatic line 310 in response to receiving an on/off signal. For example, when vacuum pressure is supplied through the vacuum port 204 of the vacuum ejector 200, the second shut-off valve 350 may operate to block the second pneumatic line 320, and when air pressure is supplied through the vacuum port 204 of the vacuum ejector 200, the first shut-off valve 340 may operate to block the first pneumatic line 310.

As illustrated in FIG. 6A, when vacuum pressure is supplied from the vacuum ejector 200 to the first port 302 of the filter assembly 300, the second pneumatic line 320 may be blocked by the second shut-off valve 350, and gas may flow from the second port 306 to the first port 302 through the first pneumatic line 310, so that the picker nozzle 400 may adsorb and hold the semiconductor package P. At this time, foreign substances in the gas flowing through the first pneumatic line 310 may be filtered and removed by the filter 330.

As illustrated in FIG. 6B, when air pressure is supplied from the vacuum ejector 200 to the first port 302 of the filter assembly 300, the first pneumatic line 310 may be blocked by the first shut-off valve 340, and gas may flow from the first port 302 to the second port 306 through the second pneumatic line 320, so that the suction of the picker nozzle 400 may be released.

As mentioned above, the filter assembly 300, as the pneumatic filtering device of the pick-and-place apparatus 10, may supply the vacuum pressure and the air pressure from the vacuum ejector 200 to the picker nozzle 400. The filter assembly 300 may include the first pneumatic line 310 connecting the first port 302 and the second port 306, the filter 330 installed in the first pneumatic line 310, the second pneumatic line 320 branched from the first pneumatic line 310 to allow gas to bypass the filter 330, the first shut-off valve 340 installed in the first pneumatic line 310 and configured to block the flow of gas from the first port 302 to the second port 306, and the second shut-off valve 350 installed in the second pneumatic line 320 and configured to block the flow of gas from the second port 306 to the first port 302.

The filter 330 installed in the first pneumatic line 310 may be configured to collect foreign substances such as dust by filtering the gas sucked from the picker nozzle 400 during a gripping operation of the picker nozzle 400. During a gripping release operation of the picker nozzle 400, the first pneumatic line 310 may be blocked and air pressure may be supplied to the picker nozzle 400 through the second pneumatic line 320. Accordingly, the dust collected in the filter 330 installed in the first pneumatic line 310 may be prevented from leaking into the process equipment through the picker nozzle 400 and contaminating the inside of the process equipment and the surface of the product such as the semiconductor package P (or leaking into the process equipment and contaminating may be reduced).

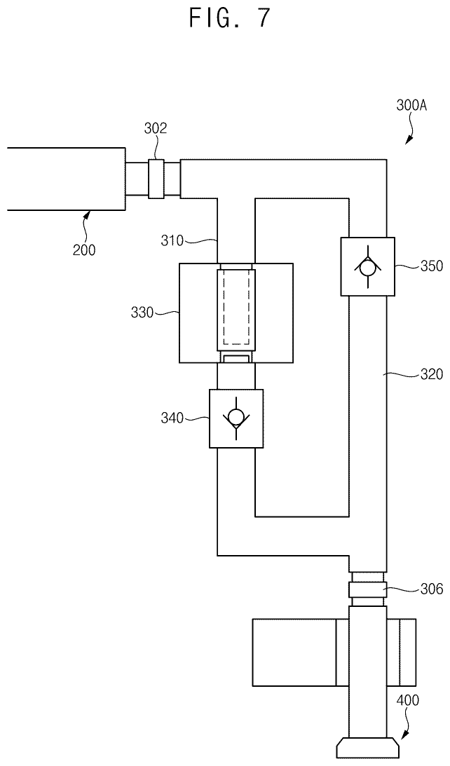

FIG. 7 is a cross-sectional view illustrating a filter assembly for a pick-and-place apparatus in accordance with example embodiments. The filter assembly 300A depicted in FIG. 7 may be substantially the same as the filter assembly 300 described with reference to FIG. 5 except for an installation position of a first shut-off valve. Thus, same reference numerals will be used to refer to the same or like elements and any further repetitive explanation concerning the above elements will be omitted.

Referring to FIG. 7, a filter assembly 300A for a pick-and-place apparatus may include a first pneumatic line 310 connecting a first port 302 and a second port 306, a filter 330 installed in the first pneumatic line 310, a second pneumatic line 320 branched from the first pneumatic line 310 to allow gas to bypass the filter 330, a first shut-off valve 340 installed in the first pneumatic line 310 and configured to block the flow of gas from the first port 302 to the second port 306, and a second shut-off valve 350 installed in the second pneumatic line 320 and configured to block the flow of gas from the second port 306 to the first port 302.

In some example embodiments, the first shut-off valve 340 may be installed in the first pneumatic line 310 between the second port 306 and the filter 330. The first shut-off valve 340 may be installed in a rear end portion of the filter 330. The first shut-off valve 340 may include a one-way check valve. An installation position of the first shut-off valve 340 may be determined in consideration of a location of the filter 330 within the filter assembly 300A, an arrangement of a vacuum ejector 200, a picker module PM, and connecting tubes connecting them, but example embodiments are not limited thereto.

Hereinafter, a process of transporting a semiconductor package using the pick-and-place apparatus will be described.

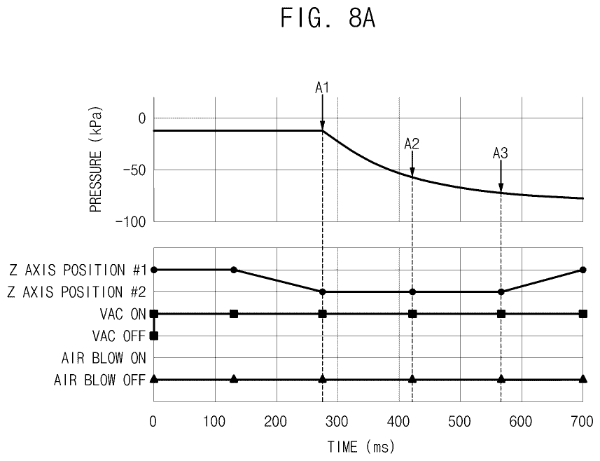

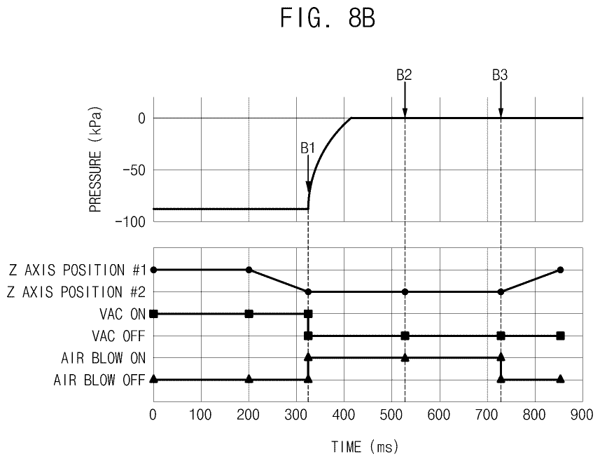

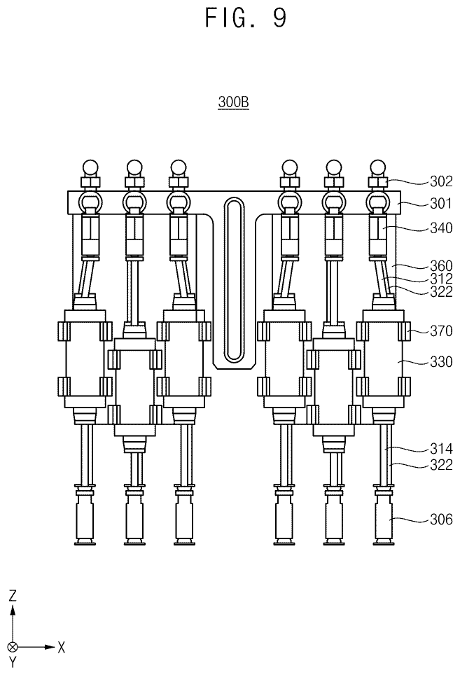

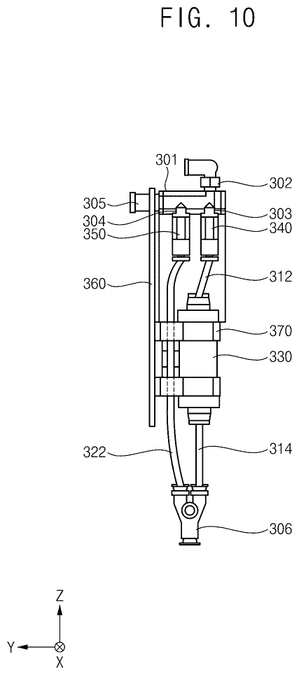

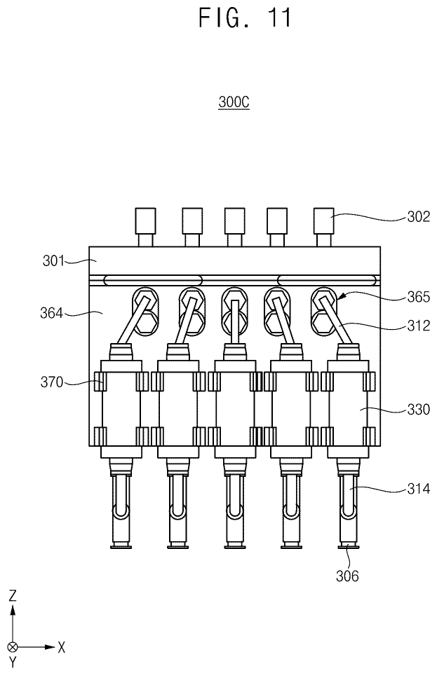

FIG. 8A is a timing diagram illustrating a pick-up step, and FIG. 8B is a timing diagram illustrating a place step. Although the below description of the timing diagram illustrated in FIGS. 8A and 8B refers to the filter assembly 300, example embodiments are not limited thereto. For example, the timing diagram illustrated in FIGS. 8A and 8B may be timing diagrams for the filter assembly 300A (depicted in FIG. 7), the filter assembly 300B (depicted in FIGS. 9-10), and/or the filter assembly 300C (depicted in FIGS. 11-13).

Referring to FIG. 8A, first, a first solenoid valve 222a of a vacuum ejector 200 may be operated by a VAC ON signal (or in response to receiving a VAC ON signal), and vacuum pressure may be supplied to a picker nozzle 400 through a filter assembly 300 connected to a vacuum port 204. From a first time A1 to a second time A2, the picker nozzle 400 may descend from a first position (#1) to a second position (#2) toward a semiconductor package P to start adsorption, and from the second time 2 to a third time A3, the adsorption may be completed and a transport may be started. At this time, a Z-axis lowering delay time may occur from the first time A1 to the second time A2, and a delay time due to the check valve of the filter assembly may occur from the second time A2 to the third time A3. Accordingly, an intake delay time may occur from the first time A1 to the third time A3. The intake delay time may be within a range of approximately 60 ms to 100 ms, but example embodiments are not limited thereto.

Referring to FIG. 8B, first, the picker nozzle 400 suctioning the semiconductor package P may be lowered from the first position (#1) to the second position (#2), and at a first time B1, a second solenoid valve 222b of the vacuum ejector 200 may be operated by a VAC OFF signal (or in response to receiving a VAC OFF signal), and air pressure may be supplied to the picker nozzle 400 through the filter assembly 300 connected to the vacuum port 204. The release of the grip may be completed from a second time B2 to a third time B3. At this time, a Z-axis lowering delay time may occur from the first time B1 to the second time B2, and a delay time due to the check valve may occur from the second time B2 to the third time B3. Accordingly, an exhaust delay time may occur from the first time B1 to the third time B3. The exhaust delay time may be within a range of approximately 60 ms to 100 ms, but example embodiments are not limited thereto.

Hereinafter, various types of filter assemblies will be described.

FIG. 9 is a plan view illustrating a filter assembly in accordance with example embodiments. FIG. 10 is a side view illustrating the filter assembly of FIG. 9. The filter assembly 300B depicted in FIGS. 9-10 may be similar or configured similar to the filter assembly 300 and/or 300A. Thus, same reference numerals will be used to refer to the same or like elements and any further repetitive explanation concerning the above elements will be omitted.

Referring to FIGS. 9 and 10, a filter assembly 300B may include a passage block 301 extending in a first direction (X direction). The passage block 301 may be installed on a vertical support frame by a fastening member 305 such as a fastening bolt, but example embodiments are not limited thereto. A first port 302 may be connected to an upper surface of the passage block 301. A plurality of the first ports 302 may be spaced apart from each other along the first direction (X direction). Accordingly, the filter assembly 300B may be provided as a filter module FM that may serve (or function) as a plurality of filtering devices sequentially connected to the first ports 302 of the passage block 301.

In some example embodiments, the passage block 301 may have an intake passage 303 formed therein and connected to the first port 302 and an exhaust passage 304 branched from the intake passage 303. A first check valve 340 may be connected to the intake passage 303 of the passage block 301. One end portion of the intake passage 303 may be open from a lower surface of the passage block 301, and the first check valve 340 may be connected to the open-end portion of the intake passage 303. A second check valve 350 may be connected to the exhaust passage 304 of the passage block 301. One end portion of the exhaust passage 304 may be open from the lower surface of the passage block 301, and the second check valve 350 may be connected to the open-end portion of the exhaust passage 304. The first check valve 340 and the second check valve 350 may be spaced apart from each other in a second direction (Y direction) on the lower surface of the passage block 301.

In some example embodiments, the filter assembly 300B may further include a bracket 360 extending in a vertical direction (Z direction). The bracket 360 may be installed on the vertical support frame. For example, a through hole may be formed in an upper end portion of the bracket 360, and a fastening member 305 may be inserted and fixed into the through hole to fasten the bracket 360 to the vertical support frame. The fastening member 305 may fasten the passage block 301 and the bracket 360 together to the vertical support frame. However, the present inventive concepts may not be limited thereto, and the bracket 360 may be fastened to the vertical support frame by a separate fastening member.

A filter 330 may be supported on one side surface of the bracket 360. The filter 330 may be secured on the one side surface of the bracket 360 by a holder 370. The holder 370 may include a U-shaped fixing clip extending from the one side surface of the bracket 360. The U-shaped fixing clip may extend to surround a perimeter of the filter 330. A first pneumatic tube 312 may connect the first check valve 340 and the filter 330. A second pneumatic tube 314 may connect the filter 330 and the second port 306. The intake passage 303, the first pneumatic tube 312 and the second pneumatic tube 314 of the passage block 301 may be provided as at least a portion of an intake line connecting the first port 302 and the second port 306.

A third pneumatic tube 322 may be provided to connect the second check valve 350 and the second port 306. The exhaust passage 304 and the third pneumatic tube 322 of the passage block 301 may be provided as at least a portion of a bypass line connecting the first port 302 and the second port 306.

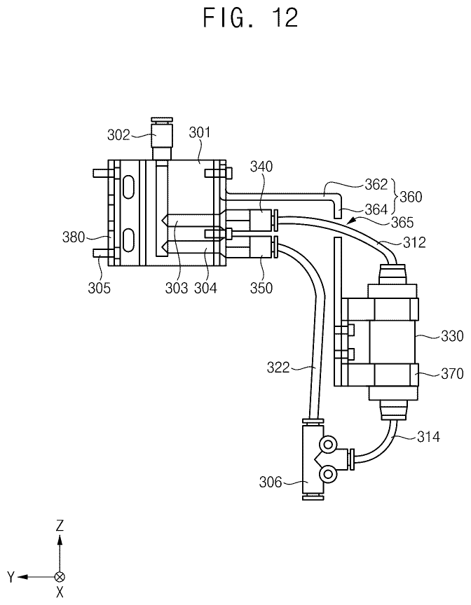

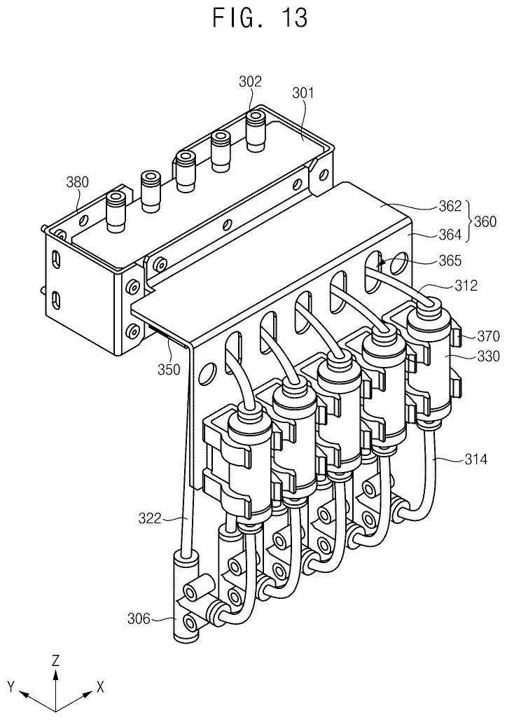

FIG. 11 is a plan view illustrating a filter assembly in accordance with some example embodiments. FIG. 12 is a side view illustrating the filter assembly of FIG. 11. FIG. 13 is a perspective view illustrating the filter assembly of FIG. 11. The filter assembly 300C depicted in FIGS. 11-13 may be similar or configured similar to the filter assembly 300, 300A, and/or 300B. Thus, same reference numerals will be used to refer to the same or like elements and any further repetitive explanation concerning the above elements will be omitted.

Referring to FIGS. 11 to 13, a filter assembly 300C may include a passage block 301 extending in a first direction (X direction). The passage block 301 may be fixed to a mounting panel 380, and the mounting panel 308 may be fixedly installed to a vertical support frame. A first port 302 may be connected to an upper surface of the passage block 301. A plurality of the first ports 302 may be spaced apart from each other along the first direction (X direction). Accordingly, the filter assembly 300C may be provided as a filter module FM that may function as a plurality of filtering devices sequentially connected to the first ports 302 of the passage block 301.

In some example embodiments, the passage block 301 may have an intake passage 303 formed therein and connected to the first port 302 and an exhaust passage 304 branched from the intake passage 303. A first check valve 340 may be connected to the intake passage 303 of the passage block 301. One end portion of the intake passage 303 may be open from a front side surface of the passage block 301, and the first check valve 340 may be connected to the open-end portion of the intake passage 303. A second check valve 350 may be connected to the exhaust passage 304 of the passage block 301. One end portion of the exhaust passage 304 may be open from the front side surface of the passage block 301, and the second check valve 350 may be connected to the open-end portion of the exhaust passage 304. The first check valve 340 and the second check valve 350 may be spaced apart from each other in a vertical direction (Z direction) on the front side surface of the passage block 301.

In some example embodiments, the filter assembly 300C may further include a bracket 360 secured to the passage block 301. The bracket 360 may include a first plate 362 extending upwardly from the front side surface of the passage block 301 and a second plate 364 extending downwardly in the vertical direction (Z direction) from the first plate 362. The first plate 362 of the bracket 360 may be secured to the front side surface of the passage block 301 by a fastening member such as a fastening bolt. The filter 330 may be supported on one surface of the second plate 354 of the bracket 360.

A filter 330 may be secured on one surface of the second plate 364 of the bracket 360 by a holder 370. The holder 370 may include a U-shaped fixing clip extending from one side of the second plate 364. The U-shaped fixing clip may extend to surround a perimeter of the filter 330.

The first check valve 340 and the second check valve 350 may be arranged in a space between the front side surface of the passage block 301 and the second plate 354. A first pneumatic tube 312 may connect the first check valve 340 and the filter 330. The first pneumatic tube 312 may be connected from the first check valve 340 to the filter 330 on one side of the second plate 354 through a through hole 365 formed in the second plate 354. A second pneumatic tube 314 may connect the filter 330 and the second port 306. The intake passage 303, the first pneumatic tube 312 and the second pneumatic tube 314 of the passage block 301 may be provided as at least a portion of an intake line connecting the first port 302 and the second port 306.

A third pneumatic tube 322 may be provided to connect the second check valve 350 and the second port 306. The exhaust passage 304 and the third pneumatic tube 322 of the passage block 301 may be provided as at least a portion of a bypass line connecting the first port 302 and the second port 306.

In some example embodiments, the pick-and-place apparatus 10 described herein may be configured to operate with one or more of the filter assembly 300, 300A, 300B, and/or 300C.

The foregoing is illustrative of some example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A pick-and-place apparatus, comprising:
a picker module having at least one picker nozzle configured to adsorb or release a semiconductor device by vacuum pressure and air pressure;
a vacuum ejector configured to selectively supply any one of the vacuum pressure and the air pressure to the at least one picker nozzle; and
a filter assembly configured to supply the vacuum pressure and the air pressure from the vacuum ejector to the at least one picker nozzle,
wherein the filter assembly includes:
a first pneumatic line connecting a first port connected to the vacuum ejector and a second port connected to the at least one picker nozzle;
a filter in the first pneumatic line, the filter being configured to filter gas flowing from the second port to the first port;
a second pneumatic line branched from the first pneumatic line in a front-end portion and in a rear-end portion of the filter to allow the gas to bypass the filter;
a first shut-off valve in the first pneumatic line, the first shut-off valve being configured to block flow of gas from the first port to the second port; and
a second shut-off valve in the second pneumatic line, the second shut-off valve being configured to block flow of gas from the second port to the first port.

2. The pick-and-place apparatus of claim 1, wherein the first shut-off valve includes a first check valve configured to open and close based on a differential pressure between the first port and the second port, and the second shut-off valve includes a second check valve configured to open and close based on a differential pressure between the second port and the first port.

3. The pick-and-place apparatus of claim 2, wherein the first check valve is configured to close when the air pressure from the vacuum ejector is supplied to the first port, and the second check valve is configured to close when the vacuum pressure from the vacuum ejector is supplied to the first port.

4. The pick-and-place apparatus of claim 2, wherein the filter assembly further includes a passage block to which the first port is connected, the passage block including an intake passage connected to the first port and an exhaust passage branched from the intake passage,
wherein the first check valve is connected to the intake passage of the passage block, and
wherein the second check valve is connected to the exhaust passage of the passage block.

5. The pick-and-place apparatus of claim 4, wherein the filter assembly further comprises:
a bracket for mounting and supporting the filter;
a first pneumatic tube connecting the first check valve and the filter;
a second pneumatic tube connecting the filter and the second port; and
a third pneumatic tube connecting the second check valve and the second port.

6. The pick-and-place apparatus of claim 4, wherein the passage block of the filter assembly is mounted on a vertical support frame that extends in a vertical direction.

7. The pick-and-place apparatus of claim 1, wherein the first shut-off valve is in the first pneumatic line between the first port and the filter.

8. The pick-and-place apparatus of claim 1, wherein the first shut-off valve is in the first pneumatic line between the second port and the filter.

9. The pick-and-place apparatus of claim 1, wherein the picker module includes a mounting body extending in a first direction and a plurality of picker nozzles sequentially mounted on the mounting body in the first direction,
wherein the vacuum ejector includes a plurality of manifold blocks for selectively supplying the vacuum pressure and the air pressure to a respective picker nozzle of the plurality of picker nozzles, and
wherein the filter assembly is configured to supply the vacuum pressure and the air pressure from a respective manifold block of the plurality of manifold blocks to a respective picker nozzle of the plurality of picker nozzles.

10. The pick-and-place apparatus of claim 1, further comprising:
a vertical support frame extending in a vertical direction,
wherein the picker module, the vacuum ejector, and the filter assembly are on the vertical support frame.

11. A pick-and-place apparatus, comprising:
a picker module having a plurality of picker nozzles, each picker nozzle of the plurality of picker nozzles being configured to adsorb or release a semiconductor device by vacuum pressure and air pressure;
a vacuum ejector having a plurality of manifold blocks for selectively supplying any one of the vacuum pressure and the air pressure to a respective picker nozzle of the plurality of picker nozzles; and
a filter assembly configured to supply the vacuum pressure and the air pressure from the plurality of manifold blocks to each picker nozzle of the plurality of picker nozzles,
wherein the filter assembly includes:
an intake line connecting a first port connected to a manifold block of the plurality of manifold blocks and a second port connected to a picker nozzle of the plurality of picker nozzles;
a filter in the intake line, the filter being configured to filter gas flowing from the second port to the first port;
a bypass line branched from the intake line in a front-end portion and a rear-end portion of the filter to allow gas to bypass the filter;
a first check valve in the intake line to block flow of gas from the first port to the second port; and
a second check valve in the bypass line to block flow of gas from the second port to the first port.

12. The pick-and-place apparatus of claim 11, wherein the first check valve is closed when the air pressure from the manifold block is supplied to the first port, and the second check valve is closed when the vacuum pressure from the manifold block is supplied to the first port.

13. The pick-and-place apparatus of claim 11, wherein the first check valve is closed when the air pressure at the first port is greater than the air pressure at the second port, and the second check valve is closed when the air pressure at the second port is greater than the air pressure at the first port.

14. The pick-and-place apparatus of claim 11, wherein the filter assembly further includes a passage block connected to the first port, the passage block including an intake passage connected to the first port, and an exhaust passage branched from the intake passage,
wherein the first check valve is connected to the intake passage of the passage block, and
wherein the second check valve is connected to the exhaust passage of the passage block.

15. The pick-and-place apparatus of claim 14, wherein the filter assembly further comprises:
a bracket for mounting and supporting the filter;
a first pneumatic tube connecting the first check valve and the filter;
a second pneumatic tube connecting the filter and the second port; and
a third pneumatic tube connecting the second check valve and the second port.

16. The pick-and-place apparatus of claim 14, wherein the passage block of the filter assembly is mounted on a vertical support frame that extends in a vertical direction.

17. The pick-and-place apparatus of claim 11, wherein the first check valve is in the intake line between the first port and the filter.

18. The pick-and-place apparatus of claim 11, wherein the first check valve is in the intake line between the second port and the filter.

19. The pick-and-place apparatus of claim 11, wherein the picker module includes a mounting body extending in a first direction and the plurality of picker nozzles sequentially mounted on the mounting body in the first direction.

20. The pick-and-place apparatus of claim 11, further comprising:
a vertical support frame that extends in a vertical direction,
wherein the picker module, the vacuum ejector, and the filter assembly are on the vertical support frame.

21.-30. (canceled)
